(19) United States
(12) Patent Application Publication
(10) Pub. No.: US 2008/0217678 A1
(43) Pub. Date: Sep. 11, 2008

(54) Memory Gate Stack Structure

(75) Inventors: Yan Ny Tan, Singapore (SG); Wai Kim Chim, Singapore (SG); Byung Jin Cho, Singapore (SG); Wee Kiong Choi, Singapore (SG)

Correspondence Address: Lipsitz & McAllister, LLC, 755 MAIN STREET, MONROE, CT, 06468, US

(73) Assignee: National University of Singapore, Singapore (SG)

(21) Appl. No.: 10/592,632

(22) PCT Filed: Mar. 11, 2004
(86) PCT No.: PCT/SG2004/000050

§ 371 Date: Mar. 14, 2008

(51) Int. Cl. H01L 29/792; H01L 21/336

(52) U.S. Cl. 257/324; 438/287; 257/E29.309; 257/E21.423

(57) ABSTRACT

A memory gate stack structure (100) comprising a substrate layer (102) comprising a silicon-based material, a tunnel layer (104) formed on the substrate layer, a charge storage layer (106) formed on the tunnel layer and comprising a hafnium-aluminium-oxide-based material, a blocking layer (108) formed on the charge storage layer, and a gate layer (110) formed on the blocking layer.

### FIELD OF INVENTION

The present invention relates broadly to a memory gate stack structure, and to a method of fabricating a memory gate stack structure. The present invention will be described herein with reference to a gate stack for a memory transistor structure, however, it will be appreciated that the present invention does have broader applications. For example it may be applied in capacitor memory structures.

### BACKGROUND

The applications of digital electronics have resulted in a demand for nonvolatile memories that are densely integrated, fast, and consume little power. The metal-oxide-nitride-oxide-semiconductor (MONOS) device is a promising candidate to replace existing forms of flash memory.

The MONOS structure has better charge retention than for example a polysilicon floating-gate type memory as the charges are stored in spatially isolated deep-level traps. Hence, a single defect in the tunnel oxide will generally not cause the discharge of the memory cell.

In MONOS device operation, electrons are involved in the program operation while both electrons and holes are involved in the erase operation. Hence threshold voltage control after erasing is difficult. If the electrical erase continues beyond a specified point, it will result in more positive charges in the silicon nitride (Si₃N₄) storage layer, resulting in over-erase.

A need exists, therefore, to provide a memory gate stack structure in which over-erase effects are reduced, while maintaining acceptable charge retention. In at least preferred embodiment, the present invention addresses that need.

### SUMMARY OF THE INVENTION

In accordance with a first aspect of the present invention there is provided a memory gate stack structure comprising:

a substrate layer comprising a silicon-based material,

a tunnel layer formed on the substrate layer,

a charge storage layer formed on the tunnel layer and comprising a hafnium-aluminium-oxide-based material,

a blocking layer formed on the charge storage layer, and

a gate layer formed on the blocking layer.

The charge storage layer may comprise (HfO₂)ₓ(Al₂O₃)₁₋ₓ, with x in a range from about 0.4 to 0.95. In one embodiment, x is about 0.9.

The tunnel layer and/or the blocking layer may comprise silica-based materials.

In one embodiment, the tunnel layer comprises a silicon oxide formed by rapid thermal oxidation of the silicon-based material of the substrate layer.

The gate layer may comprise a metal, metal nitride, silicide or polysilicon materials. In one embodiment, the metal material may comprise HfN.

The memory gate stack structure may further comprise a capping layer on the gate layer. In one embodiment the capping layer may comprise TaN.

The blocking layer comprise (Si(OC₂H₅)₄).

In accordance with a second aspect of the present invention there is provided a method of fabricating a memory gate stack structure, comprising the steps of:

providing a substrate layer comprising a silicon-based material,

forming a tunnel layer on the substrate layer,

forming a charge storage layer on the tunnel layer and comprising a hafnium-aluminium-oxide-based material,

forming a blocking layer on the charge storage layer, and

forming a gate layer on the blocking layer.

The charge storage layer may comprise (HfO₂)ₓ(Al₂O₃)₁₋ₓ, with x in a range from about 0.4 to 0.95. In one embodiment, x is about 0.9.

The tunnel layer and/or the blocking layer may comprise silica-based materials.

In one embodiment, the tunnel layer comprises a silicon oxide formed by rapid thermal oxidation of the silicon-based material of the substrate layer.

The blocking layer may comprise (Si(OC₂H₅)₄). The blocking layer may be formed utilising low-pressure chemical-vapor-deposition (CVD).

The gate layer may comprise a metal, metal nitride, silicide or polysilicon materials. In one embodiment, the metal material may comprise HfN.

The gate layer may be formed utilising sputter deposition techniques.

The method may further comprise the step of forming a capping layer on the gate layer. In one embodiment, the capping layer may comprise TaN.

The capping layer may be formed utilising sputter deposition techniques.

In accordance with a third aspect of the present invention there is provided a memory gate stack structure comprising:

a substrate layer comprising a silicon-based material,

a tunnel layer formed on the substrate layer,

a charge storage layer formed on the tunnel layer,

a blocking layer formed on the charge storage layer, and

a gate layer formed on the blocking layer,

wherein the charge storage layer comprises an amorphous material exhibiting a larger valence band offset with respect to the silicon-based material compared to Si₃N₄, and exhibiting a smaller conduction band offset with respect to the silicon-based material compared to Al₂O₃.

In accordance with a fourth aspect of the present invention there is provided a method of fabricating a memory gate stack structure, comprising the steps of:

providing a substrate layer comprising a silicon-based material,

forming a tunnel layer on the substrate layer,

forming a charge storage layer on the tunnel layer,

forming a blocking layer on the charge storage layer, and

forming a gate layer on the blocking layer,

wherein the charge storage layer comprises an amorphous material exhibiting a larger valence band offset with respect to the silicon-based material compared to Si₃N₄, and exhibiting a smaller conduction band offset with respect to the silicon-based material compared to Al₂O₃.

### BRIEF DESCRIPTION OF THE DRAWINGS

Embodiments of the invention will be better understood and readily apparent to one of ordinary skill in the art from the following written description, by way of example only, in conjunction with the drawings, in which:

FIG. 1 is a schematic cross-sectional view of a general memory gate stack structure.

FIG. 2(a) shows capacitance versus charging time (C-t) curves at a charging voltage of 6V, for a memory gate stack structure embodying the present invention and in comparison with other memory gate stack structures.

FIG. 2(b) shows normalised discharge C-t curves during discharging at a gate bias of −1.45V, for a memory gate stack structure embodying the present invention and in comparison with other memory gate stack structures.

FIG. 3(a) shows capacitance versus voltage curves for a memory gate stack structure embodying the present invention.

FIG. 3(b) shows capacitance versus voltage curves of another memory gate stack structure for comparison.

FIG. 3(c) shows capacitance versus voltage curves of another memory gate stack structure for comparison.

FIG. 4(a) shows plots of the density of stored charge, extracted from the curves shown in FIGS. 3(a)-(c), and plotted as a function of the range of gate voltage sweep for a memory gate stack structure embodying the present invention and in comparison with other memory gate stack structures.

FIG. 4(b) shows plots of flatband voltage shift against the charging/discharging voltage for a memory gate stack structure embodying the present invention and in comparison with other memory gate stack structures.

FIG. 5 is a schematic cross-sectional view of a memory transistor structure embodying the present invention.

FIG. 6 shows a flow-chart 600 illustrating a method of fabricating a memory gate stack structure in an embodiment of the present invention

### DETAILED DESCRIPTION

The preferred embodiment described provides a memory gate stack structure for use in a memory transistor having both an acceptable over-erase characteristic, and an acceptable charge retention capability.

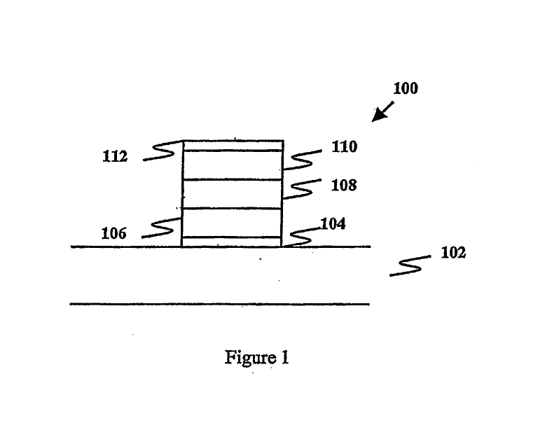

In order to obtain comparative data on the function of gate stack structures for a memory transistor, four different memory gate stack structures were fabricated and analysed. FIG. 1 is a schematic cross sectional view of the general memory gate stack structure 100, consisting of a substrate 102, a tunnel layer 104, a charge storage layer 106, a blocking layer 108, a gate layer 110, and a capping layer 112.

For each device, the processing conditions were the same except for the formation of the charge storage layer 106, that is, Si₃N₄ for a conventional MONOS device, HfO₂ for a comparative device, HfAlO (or (HfO₂)ₓ(Al₂O₃)₁₋ₓ) for a device embodying the present invention, and Al₂O₃ for another comparative device.

Details of the structures used in conjunction with an example embodiment of the invention were as follows. The substrate 102 used was 4-8 Ω-cm (100) p-type silicon. The 25 Å thick tunnel oxide 104 was grown by rapid thermal oxidation at 1000° C. After tunnel oxide formation, Si₃N₄ (60 Å) was deposited by low-pressure chemical-vapor-deposition (LPCVD) while HfO₂ (60 Å) and Al₂O₃ (60 Å) were deposited by atomic layer deposition (ALD), as the respective charge storage layers 106. (HfO₂)ₓ(Al₂O₃)₁₋ₓ with x=0.9 and abbreviated as HfAlO henceforth, was deposited as a charge storage layer 106 by metal-organic-chemical-vapor-deposition (MOCVD), followed by post-deposition-annealing (PDA) at 700° C. in nitrogen ambient for 60 seconds. The blocking oxide 108 (55 Å) was deposited as LPCVD TEOS (Si(OC₂H₅)₄). HfN metal gate electrode 110 (˜50 nm) and TaN (˜100 nm) capping layer 112 were deposited by reactive sputtering of Hf and Ta targets, respectively, in an Ar+N₂ ambient. The fabricated gate stacks had a gate area of 800×800 μm²

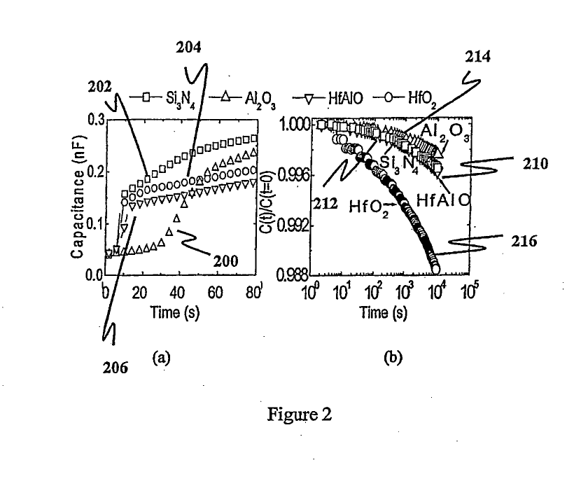

The programming speeds of the various gate stack memory structures with HfO₂, Al₂O₃, HfAlO or Si₃N₄ as the respective charge storage layers were evaluated by measuring the capacitance versus time (C-t) curve during charging at 6 V gate bias, as shown in FIG. 2(a). The slope in the C-t curve is proportional to the rate of change in the stored charge of the gate stack at a constant bias voltage. From FIG. 2(a), it can be seen that the Al₂O₃ device (curve 200) charges up much more slowly as compared to the other memory gate stacks (curves 202, 204, and 206).

The charge retention performance was evaluated by measuring the C-t characteristics, after the device has been charged at 6 V for 80 s, at a constant discharge gate bias of −1.45 V with respect to the initial flatband voltage of the charged device. FIG. 2(b) shows the normalized discharge C-t, or C(t)/C(t=0), curves. From FIG. 2(b) it can be seen that HfAlO (curve 210) has comparable charge retention performance to Si₃N₄ (curve 212). Al₂O₃ (curve 214) has the best retention characteristics while HfO₂ (curve 216) has the worst retention. From the results shown in FIG. 2, it was discovered that there is a tradeoff between programming speed and charge retention. It was recognised that as deposited HfO₂ is already crystallized while HfAlO is still amorphous even after annealing at 700° C., 60 s. From FIG. 2(b), the amorphous films, which are Si₃N₄, Al₂O₃ and HfAlO (curves 212, 214 and 210 respectively), show significantly better retention performance compared to crystallized HfO₂ (curve 216). Polycrystallization of thin films may generate grain boundaries, which may act as current leakage paths.

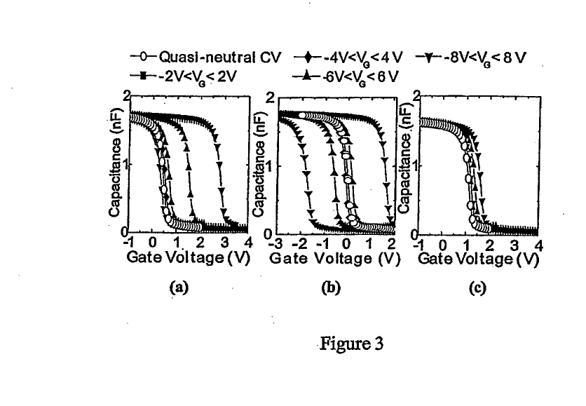

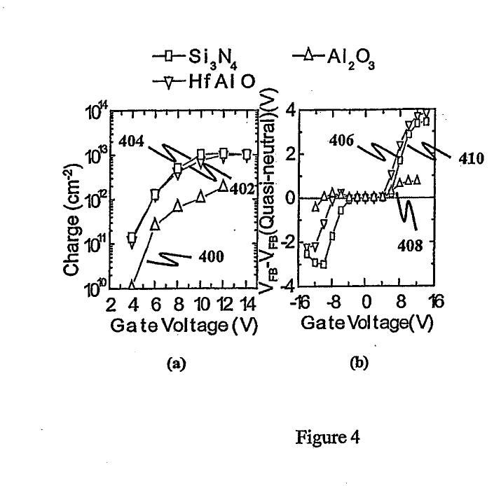

The charge storage performance of memory devices with good retention characteristics, namely those with Al₂O₃, HfAlO or Si₃N₄ as the respective charge storage layers (curves 214, 210 and 212 respectively), was further investigated by measuring the hysteresis in the capacitance-voltage (C-V) curves. The C-V curves with counter-clockwise hysteresis are shown in FIGS. 3(a), (b) and (c), for HfAlO, Si₃N₄ and Al₂O₃ respectively. It can be seen from FIG. 3 and FIG. 4(a), which summarises the charge storage characteristics over the gate voltage, that the charge storage capability of Al₂O₃ devices (FIG. 3(c) and curve 400 in FIG. 4(a)) is the smallest while that of HfAlO (FIG. 3(a) and curve 402 in FIG. 4(a)) and Si₃N₄ (FIG. 3(b) and curve 404 in FIG. 4(a)) devices are comparable.

FIG. 4(b) shows the shift in flatband voltage from that of the quasi-neutral condition, whereby the gate voltage sweep is restricted to a very small range to minimize charging of the device, for positive (program) and negative (erase) gate voltages. Both HfAlO and Al₂O₃ devices (curves 406 and 408 respectively) show better over-erase performance than Si₃N₄ devices (curve 410), with over-erase free characteristics up to a negative gate voltage sweep of −8 V and −10 V for HfAlO and Al₂O₃ devices, respectively, as compared to −4 V for Si₃N₄ devices. However, the Al₂O₃ device has the smallest charge storage capacity and the slowest charging rate of the three memory structures (see curve 400 in FIG. 4(a) and curve 200 in FIG. 2(a)). Using HfAlO as the charge storage layer in the preferred embodiment results in optimization of the charge storage and erase performance of the memory structure.

The observed differences in charge storage and electron/hole injection (i.e., program/erase) characteristics and programming speed of the various structures may be explained by differences in the bandgap, valence and conduction band offsets of the various films with respect to silicon. The valence band offset of Si₃N₄ with respect to Si is the smallest, at 2 eV, compared to 3.3 eV for HfAlO and 4.9 eV for Al₂O₃. The conduction band offset between HfAlO and Si is the smallest, at 1.6 eV, as compared to 2 eV for Si₃N₄ and 2.8 eV for Al₂O₃.

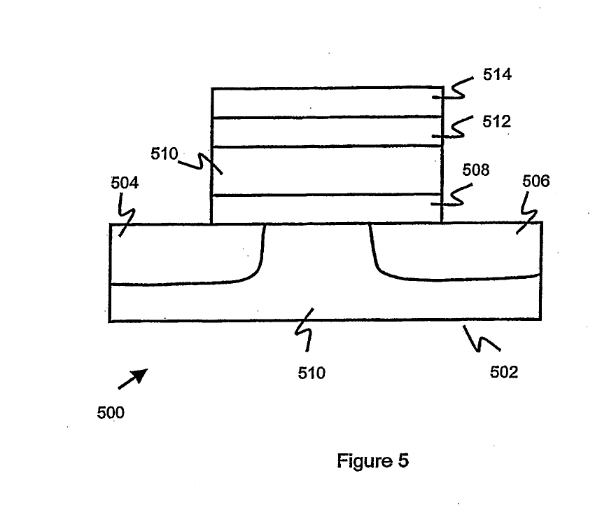

FIG. 5 is a schematic cross-sectional drawing of a memory transistor structure 500. The memory transistor structure 500 comprises a silicon-based substrate layer 502, in which a source region 504 and a drain region 506 are formed, for example through appropriate doping in the respective areas. A tunnel layer 508 is formed on the substrate layer 502, and extends over the substrate region 510 between the source and drain regions 504 and 506 respectively. The tunnel layer also extends over portions of the source and drain regions 504, 506 respectively.

A charge storage layer 510 comprising a hafnium-aluminium-oxide-based material is formed on the tunnel layer 508. A blocking layer 512 is formed on the charge storage layer 510, and a gate layer 514 is formed on the blocking layer 512, completing the memory transistor structure 500 in an example embodiment.

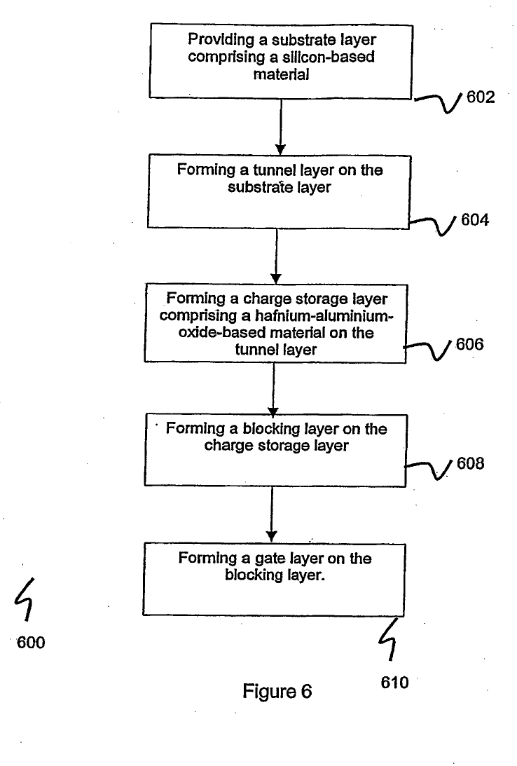

FIG. 6 shows a flow-chart 600 illustrating a method of fabricating a memory gate stack structure in an embodiment of the present invention. It comprises, at step 602, providing a substrate layer comprising a silicon-based material. At step 604, a tunnel layer is formed on the substrate layer. At step 606, a charge storage layer comprising a hafnium-aluminium-oxide-based material is formed on the tunnel layer. A blocking layer is formed on the charge storage layer at step 608, and, at step 610, a gate layer is formed on the blocking layer.

In the foregoing manner, a memory gate stack structure for e.g. a memory transistor and a method for fabricating the same are disclosed. Only several embodiments are described. However, it will be apparent to one skilled in the art in view of this disclosure that numerous changes and/or modifications may be made without departing from the scope of the invention.

For example, it will be appreciated by the person skilled in the art that the present invention is not limited to the deposition techniques and/or dimensioning of the memory gate stack structure of the embodiments described. In other embodiments, the thickness of the tunnel layer may, for example, be in the range from, but is not limited to, about 10 to 100 Å, the charge storage layer thickness may be in the range from, but is not limited to, about 30 to 200 Å, and the blocking layer thickness may be in the range from, but is not limited to, about 30 to 200 Å.

Also, the gate layer may be made from a different material including, for example, one or more of metal, metal nitride, silicide or polysilicon materials. Also, the charge storage layer may be formed from different hafnium-aluminium-oxide-based materials, including e.g. (HfO₂)ₓ(Al₂O₃)₁₋ₓ, with x in the range from about 0.4 to 0.95.

1. A memory gate stack structure comprising:
a substrate layer comprising a silicon-based material,
a tunnel layer formed on the substrate layer,
a charge storage layer formed on the tunnel layer and comprising a hafnium-aluminium-oxide-based material,
a blocking layer formed on the charge storage layer, and
a gate layer formed on the blocking layer.

2. The memory gate stack structure as claimed in claim 1, wherein the charge storage layer comprises (HfO₂)ₓ(Al₂O₃)₁₋ₓ, with x in a range from about 0.4 to 0.95.

3. The memory gate stack structure as claimed in claim 2, wherein x is about 0.9.

4. The memory gate stack structure as claimed in claim 1, wherein the tunnel layer and/or the blocking layer comprise one or more silica-based materials.

5. The memory gate stack structure as claimed in claim 4, wherein the tunnel layer comprises a silicon oxide formed by rapid thermal oxidation of the silicon-based material of the substrate layer.

6. The memory gate stack structure as claimed in claim 4, wherein the blocking layer comprises (Si(OC₂H₅)₄).

7. The memory gate stack structure as claimed in claim 1, wherein the gate layer comprises one or more of a group comprising a metal, metal nitride, silicide and polysilicon materials.

8. The memory gate stack structure as claimed in claim 7, wherein the metal material comprises HfN.

9. The memory gate stack structure as claimed in claim 1, wherein the memory gate stack structure further comprises a capping layer on the gate layer.

10. The memory gate stack structure as claimed in claim 9, wherein the capping layer comprises TaN.

11. The memory gate stack structure as claimed in claim 1, wherein the substrate layer comprises a source region and a drain region.

12. A method of fabricating a memory gate stack structure, comprising the steps of:
providing a substrate layer comprising a silicon-based material,
forming a tunnel layer on the substrate layer,
forming a charge storage layer on the tunnel layer and comprising a hafnium-aluminium-oxide-based material,
forming a blocking layer on the charge storage layer, and
forming a gate layer on the blocking layer.

13. The method as claimed in 12, wherein the charge storage layer comprises (HfO₂)ₓ(Al₂O₃)₁₋ₓ, with x in arrange from about 0.4 to 0.95.

14. The method as claimed in claim 13, wherein x is about 0.9.

15. The method as claimed in claim 12, wherein the tunnel layer and/or the blocking layer comprise one or more silica-based materials.

16. The method as claimed in claim 15, wherein the tunnel layer comprises a silicon oxide formed by rapid thermal oxidation of the silicon-based material of the substrate layer.

17. The method as claimed in claim 15, wherein the blocking layer comprises (Si(OC₂H₅)₄).

18. The method as claimed in claim 12, wherein the blocking layer is formed utilising low-pressure chemical-vapor-deposition.

19. The method as claimed in claim 12, wherein the gate layer comprises one or more of a group comprising a metal, metal nitride, silicide and polysilicon materials.

20. The method as claimed in claim 19, wherein the metal material comprises HfN.

21. The method as claimed in claim 19, wherein the gate layer is formed utilising sputter deposition techniques.

22. The method as claimed in claim 12, wherein the method further comprises the step of forming a capping layer on the gate layer.

23. The method as claimed in claim 22, wherein the capping layer comprises TaN.

24. The method as claimed in claim 22, wherein the capping layer is formed utilising sputter deposition techniques.

25. The method as claimed in claim 12, further comprising the step of forming a source region and a drain region in the substrate layer.

26. A memory gate stack structure comprising:
a substrate layer comprising a silicon-based material,
a tunnel layer formed on the substrate layer,
a charge storage layer formed on the tunnel layer,
a blocking layer formed on the charge storage layer, and
a gate layer formed on the blocking layer,
wherein the charge storage layer comprises an amorphous material exhibiting a larger valence band offset with respect to the silicon-based material compared to Si₃N₄, and exhibiting a smaller conduction band offset with respect to the silicon-based material than Al₂O₃.

27. A method of fabricating a memory gate stack structure, comprising the steps of:
providing a substrate layer comprising a silicon-based material,
forming a tunnel layer on the substrate layer,
forming a charge storage layer on the tunnel layer,
forming a blocking layer on the charge storage layer, and
forming a gate layer on the blocking layer,
wherein the charge storage layer comprises an amorphous material exhibiting a larger valence band offset with respect to the silicon-based material compared to Si₃N₄, and exhibiting a smaller conduction band offset with respect to the silicon-based material than Al₂O₃.

28-30. (canceled)
